(19) United States
(12) Patent Application Publication
(10) Pub. No.: US 2026/0327851 A1
(43) Pub. Date: Oct. 22, 2026

(54) SPIN-INFORMATION TRANSPORT DEVICE AND METHOD OF MANUFACTURING

(71) Applicant: Deutsches Zentrum für Luft- und Raumfahrt e. V., Nordrhein-Westfalen (DE)

(72) Inventors: Christoph FINDLER, Bonn (DE); Johannes LANG, Bonn (DE); Christian OSTERKAMP, Bonn (DE)

(21) Appl. No.: 19/417,491

(22) Filed: Dec. 12, 2025

(30) Foreign Application Priority Data
Dec. 20, 2024 (DE) 102024139460.9

(51) Int. Cl. C30B 25/20; C30B 29/04; C30B 33/12; G06N 10/40

(52) U.S. Cl. CPC C30B 25/20; C30B 29/04; C30B 33/12; G06N 10/40

(57) ABSTRACT

Spin-information transport device, comprising a diamond matrix consisting of C12 diamond and two vacancy centers, in particular NV centers, within the diamond matrix, wherein a spin polarization channel, in particular consisting of C13-enriched diamond, for enabling a directional diffusion of a spin polarization extends between the two vacancy centers. The invention also relates to a method of manufacturing such a spin-information transport device.

### CROSS-REFERENCE TO RELATED APPLICATION

This application claims priority pursuant to 35 U.S.C. 119(a) to German Patent Application No. 102024139460.9, filed Dec. 20, 2024, which application is incorporated herein by reference in its entirety.

### TECHNICAL FIELD

The present invention relates to a spin-information transport device, comprising a diamond matrix consisting of C12 diamond and two vacancy centers, in particular NV centers, within the diamond matrix. The invention also relates to a method of manufacturing such a spin-information transport device.

### BACKGROUND

Producing synthetic diamonds by means of CVD (chemical vapor deposition) is a common technique for producing synthetic diamonds in industry. There is particular focus on the growth of diamond layers that have a thickness greater than 100 nm, which are predominantly produced for applications in the jewelry industry and for materials processing, e.g., as cutting tools. In these applications, only the mechanical properties of the diamonds produced are relevant, such as the hardness for example.

Recently, synthetic diamonds have also become increasingly relevant for high-tech applications, such as in quantum technology or semiconductor technology. In quantum technology, diamond is used as a matrix, into which atomic vacancy centers are introduced, such as NV centers (nitrogen vacancy centers), SiV centers (silicon vacancy centers), GeV centers (germanium vacancy centers) or SnV centers (tin vacancy centers) To make the vacancy centers usable for quantum computing, for example, they are introduced into a matrix enriched with the isotope carbon-13 (C13), which, in contrast to the isotope carbon-12 (C12), has a non-zero nuclear spin. If the distance between a vacancy center and a C13 atom is small enough, a measurable coupling occurs between the spins of the vacancy center and of the C13 atom, so that these can be used as qubits.

The vacancy centers are located in the layer of C13-enriched diamond. Provided that this layer has a sufficient density of C13 atoms and thus of C13 nuclear spins, the spin polarization can diffuse in any direction within the entire diamond layer. However, a directional diffusion of spin polarizations, which are generated as spin information by quantum manipulation of the vacancy centers, within the diamond material is therefore not possible with these diamond structures. But such directional diffusions would be necessary in order to produce more complex quantum-mechanical circuit elements.

The object of the present invention is therefore to provide a device from which more complex quantum-mechanical circuit elements can also be constructed.

This object is achieved in a device of the type mentioned above by a spin polarization channel, in particular consisting of C13-enriched diamond, for enabling a directional diffusion of a spin polarization, said spin polarization channel extending between the two vacancy centers, in particular connecting the two vacancy centers to each other.

By means of the spin polarization channel, a directional diffusion of polarization between the atomic vacancy centers can be made possible. The spin polarization channel, in particular consisting of C13-enriched synthetic diamond, can limit the spin polarization diffusion possibilities substantially to a one-dimensional diffusion. The one-dimensional diffusion of the (nuclear) spin polarization can thus take place in a manner directed along the longitudinal axis of the spin polarization channel.

The, in particular synthetic, diamond matrix consisting of C12 diamond can provide a nuclear spin-free layer, in which no diffusion of the spin polarization is possible, so that the spin polarization channel in the diamond matrix cannot be bypassed.

By means of the spin polarization channel, the spin-information transport device can transport quantum information from one vacancy center to the other. In particular, this opens up the possibility of using multiple spin-information transport devices to construct more complex quantum-mechanical circuit elements and, for example, to produce quantum transistors and coherently connect these to form a network, a qubit register.

The spin polarization channel may be very highly enriched with C13. In particular, C13 enrichment in the range from 10% to 99.99%, preferably in the range from 50% to 99.99%, is possible. Such a high C13 enrichment ensures efficient polarization diffusion, i.e., spin transport, in the spin polarization channel.

The atomic vacancy centers may be NV centers (nitrogen vacancy centers), SiV centers (silicon vacancy centers), GeV centers (germanium vacancy centers) and/or SnV centers (tin vacancy centers).

Preferably, the spin polarization channel is arranged above the vacancy centers. By arranging the spin polarization channel above the vacancy centers, the directional diffusion of the spin polarization can take place in a different plane than the generation of the spin polarization by quantum manipulation of the vacancy centers. In particular, the directional diffusion of the spin polarization can take place in a layer having a different chemical composition than the layer in which the vacancy centers are arranged.

“Above” refers to an arrangement on the side of the vacancy centers facing away from the interior of the diamond matrix, in particular facing away from a substrate. In particular, “above” can generally refer to an arrangement along a direction of growth.

The spin polarization channel may be arranged above the vacancy centers in such a way that one vacancy center is arranged below each diametrically opposite end of the spin polarization channel.

It is also advantageous if the spin polarization channel is covered by a C12 diamond protective layer. By virtue of the, in particular pure, C12 diamond protective layer, the spin polarization channel can be protected on the side facing away from the diamond matrix. By using nuclear spin-free C12 in the diamond protective layer, spin shielding of the spin polarization channel toward the outside of the device can be achieved in order to protect against spin noise. The C12 diamond protective layer may in particular have a thickness of at least 50 nm, preferably at least 100 nm.

In one embodiment, the diamond matrix is arranged on a diamond substrate. The diamond substrate can form a mechanically and chemically stable substrate for the diamond matrix. The diamond matrix may be chemically bonded to the diamond substrate, in particular grown thereon.

It is possible that the two vacancy centers are at a distance of 5 nm to 100 μm, in particular 500 nm to 1 μm. In this way, a spin polarization can be transferred between two points that are far apart for quantum-mechanical applications.

Furthermore, it is possible that the spin polarization channel has a width of 1 nm to 10 μm, preferably in the range from 5 nm to 100 nm, and/or a length of at least 5 nm, preferably at least 500 nm, particularly preferably in the range from 500 nm to 1 μm, more preferably in the range from 1 μm to 5 μm, and/or a thickness in the range from 0.5 nm to 100 nm, preferably 1 nm to 10 nm. With a spin polarization channel of this length, a spin polarization can be transferred in a directional manner over a long distance for quantum-mechanical applications. With a spin polarization channel of this width and/or thickness, measured perpendicular to the plane of the diamond matrix, the spin polarization diffusion possibilities in the spin polarization channel can easily be limited to a one-dimensional diffusion along the length of the spin polarization channel.

Furthermore, it may be advantageous if the diamond matrix has a thickness of at least 50 nm, in particular at least 100 nm. In this way, the diamond matrix can provide a mechanically stable layer for accommodating the vacancy centers.

In a method of the type mentioned above, in order to achieve the aforementioned object, it is proposed that the method comprises the steps of growing a diamond matrix consisting of C12-enriched diamond onto a diamond substrate, in particular an ultra-pure diamond substrate, by means of CVD, introducing vacancy centers into the diamond matrix, growing a C13-enriched diamond layer thereon, and partially removing the C13-enriched diamond layer, in particular by etching, to form a spin polarization channel.

By means of the method, a spin-information transport device according to the invention can be manufactured, comprising a spin polarization channel which can enable a directional diffusion of polarization between the vacancy centers. The features described in connection with the spin-information transport device according to the invention can also be used, individually or in combination, in the method. This results in the same advantages as already described.

In particular, by growing a diamond matrix consisting of C12-enriched diamond onto an ultra-pure diamond substrate by means of CVD, it is possible to prevent any undesired ingress of foreign atoms, i.e., non-carbon atoms, from the diamond substrate into the diamond matrix during further processing steps. An ultra-pure diamond substrate may have a residual nitrogen concentration of less than 5 ppb (parts per billion) remaining therein as a result of production of the diamond substrate.

The diamond matrix may have a thickness, measured along the direction of growth thereof on the diamond substrate, of at least 50 μm, in particular at least 100 μm.

A diamond matrix which is enriched with 12C, in particular which consists of C12, can easily be produced on the diamond substrate by growing it thereon by means of CVD. The diamond matrix consisting of C12-enriched diamond can provide a nuclear spin-free layer, into which the vacancy centers can be introduced. In this way, it is possible to prevent any diffusion of the spin polarization into the diamond matrix, and thus to prevent any bypassing of the spin polarization channel.

A C12-enriched methane gas can be used for the growing-on of the diamond matrix by means of CVD.

To introduce the vacancy centers, ions can be implanted into the diamond matrix. For ion implantation, ions, e.g., nitrogen ions in the case of NV centers, can be accelerated onto the diamond matrix. The ions can come to rest in the diamond matrix at a depth dependent on the acceleration energy, thus creating vacancies along their path. By way of a subsequent annealing process, the ions and vacancies can combine to form vacancy centers, e.g., NV centers in the case of ion-implemented nitrogen. The ion implantation may in particular take place using nitrogen-15 ions (15N+) at an energy of 0.1 ke V to 5 keV, preferably 1 keV, and/or at a dose of at least 10¹¹ 15 N+/cm.

The ion implantation may take place in a controlled manner, in particular by using a mask which covers the diamond matrix and which allows ion implantation only in a few predefined regions of the diamond matrix.

The ion implantation may take place in such a way that the vacancy centers are created below the specified ends of the spin polarization channel.

By growing-on the C13-enriched diamond layer, a diamond layer containing C13 nuclear spins can be created on the diamond matrix, which in particular is free of C13 nuclear spins. The C13-enriched diamond layer may also contain C12 in addition to C13, in particular may comprise predominantly C12. The C13-enriched diamond layer may be grown onto the diamond matrix, in particular directly. The C13-enriched diamond layer may have a thickness in the range from 0.5 nm to 100 nm, preferably 1 nm to 10 nm. When growing-on the diamond layer, a very low rate of growth, which is below the rates of growth normally used, may be used in order to enable the layer thickness to be set with nm accuracy.

By partially removing the C13-enriched diamond layer, the spin polarization channel can easily be formed without modifying the diamond matrix. The partial removal of the C13-enriched diamond layer may take place in such a way that the C13-enriched diamond layer is completely removed in some regions, in particular in regions which do not form a spin polarization channel. In particular, the C13-enriched diamond layer can easily be partially removed by etching. A lithographic etching process may be used for this. In this process, the region of the diamond layer that is intended to form the spin polarization channel can be covered by means of a mask, so that only the regions of the C13-enriched diamond layer that are not covered by the mask are etched away. The mask may be applied as a photoresist to the C13-enriched diamond layer. Thereafter, the C13-enriched diamond layer partially coated with the photoresist can be exposed, thus enabling the selective etching.

It may be provided that a C12 diamond protective layer is grown onto the spin polarization channel in order to increase the coherence time of the vacancy centers. The C12 diamond protective layer can protect the spin polarization channel against negative influences from the surface of the spin-information transport device. The C12 diamond protective layer may be ultra-pure, i.e., may be substantially 99.9% enriched with C12, and in particular may be free of C13. By using nuclear spin-free C12 in the diamond protective layer, spin shielding of the spin polarization channel toward the outside of the device can be achieved in order to protect against spin noise.

The C12 diamond protective layer may in particular be grown on in a thickness of at least 50 nm, preferably at least 100 nm.

Advantageously, the C13-enriched diamond layer may be grown on by means of CVD using C13-enriched methane gas. The diamond layer can easily be enriched with C13 by growing the diamond using C13-enriched growth gas, in particular methane gas. The density of the C13 nuclear spins in the grown synthetic diamond layer can be adjusted on the basis of the extent to which the growth gas is enriched with C13.

Furthermore, it may be advantageous if, in order to introduce vacancy centers into the diamond matrix, ion implantation takes place, followed by high-temperature annealing, in particular in vacuo. By implanting ions and then annealing at high temperature, ions can be introduced into the diamond matrix and then combine with the vacancies during the high-temperature annealing so as to form the vacancy centers. The high-temperature annealing may in particular take place at a temperature of 1000 °C for 3 hours in vacuo, preferably at a pressure below 10⁻⁷ mbar.

Preferably, the partial removal of the C13-enriched diamond layer takes place by means of controlled plasma etching, in particular ICP, of the surface of the C13-enriched diamond layer. By means of controlled plasma etching, diamond material can be removed from the surface of the C13-enriched diamond layer in a controlled manner with nanometer accuracy. Controlled plasma etching can be achieved by inductive plasma etching (ICP) or reactive ion etching (RIE). Inductive plasma etching can be achieved by igniting an inductively coupled plasma, in particular an oxygen plasma or an Ar/SF6 plasma (SF6: sulfur hexafluoride), and applying an accelerating voltage that accelerates the reactive ions onto the diamond layer.

Further details and advantages of a spin-information transport device according to the invention and of a method according to the invention will be explained below by way of example on the basis of an exemplary embodiment of the invention which is shown schematically in the drawings.

### BRIEF DESCRIPTION OF THE DRAWINGS

The nature and mode of the operation of the present invention will now be more fully described in the following detailed description of the invention taken with the accompanying drawing figures, in which:

FIG. 1a schematically illustrates the growth of a C¹² diamond matrix onto a diamond substrate using CVD with a C¹³-free growth gas.

FIG. 1b shows the introduction of vacancy centers (in particular NV centers) into the C¹² diamond matrix by ion implantation and subsequent high-temperature annealing.

FIGS. 1c and 1d depict the growth of a C¹³-enriched diamond layer onto the diamond matrix containing the vacancy centers.

FIG. 1e illustrates the partial removal (e.g., by lithographic ICP etching) of the C¹³-enriched diamond layer to form a spin polarization channel connecting the two vacancy centers.

FIG. 1f shows the completed spin-information transport device after growth of a C¹² diamond protective layer over the spin polarization channel and the diamond matrix.

In the drawings:

FIGS. 1a-f show the individual steps of a method of manufacturing according to the invention as well as a spin-information transport device according to the invention. To better distinguish the individual layers, these are shown spaced apart from each other in the sub-figures (FIG. 1a to FIG. 1f). However, in the spin-information transport device 1, and during the manufacturing thereof, these layers are so close together that they adjoin each other in the direction of growth W. FIG. 1a shows the first step in manufacturing the spin-information transport device 1. A diamond matrix 3 is grown onto a pure diamond substrate 2 by means of CVD. During the CVD growth, a C12-containing growth gas 8 is used. For the growth of the diamond matrix 3, this growth gas 8 is free of C13, so that the diamond matrix 3 is free of nuclear spins when growth is complete. Methane gas can be used as the growth gas 8.

A diamond matrix 3 is thus formed on the diamond substrate 2 along the direction of growth W. This diamond matrix 3 has a thickness M of at least 50 nm to 100 nm. It is therefore thick enough to be able to accommodate the vacancy centers 4 introduced in the subsequent step, without these penetrating into the diamond substrate 2.

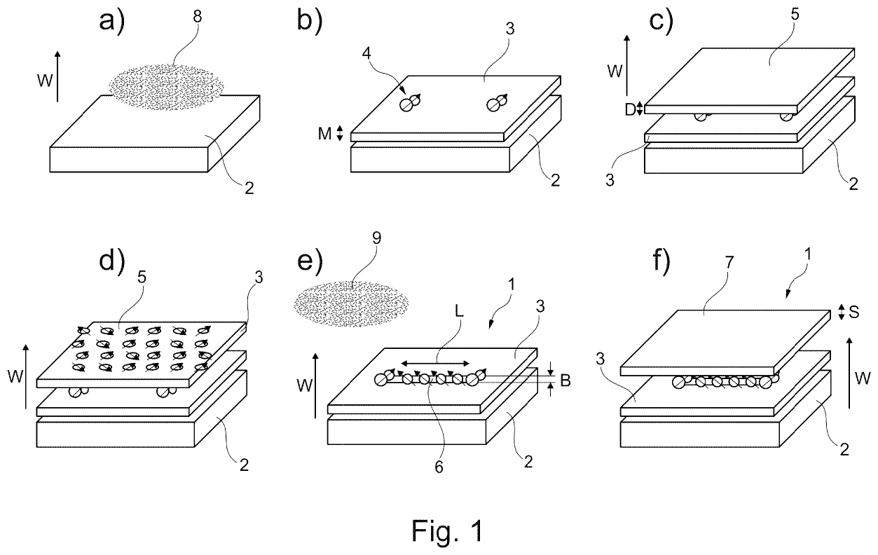

Once the diamond matrix 3 has been grown on, the vacancy centers 4 are introduced into the diamond matrix 3, as shown in FIG. 1b.

To introduce the vacancy centers 4 into the diamond matrix 3, first an ion implantation takes place. In this process, for example, nitrogen-15 ions (15N+) are accelerated onto the diamond matrix 3 at an energy of 1 keV and at a dose of 10¹¹ 15 N+/cm. The ions then come to rest in the diamond matrix 3 at a depth dependent on the acceleration energy. On their way to this rest position, the ions create vacancies in the diamond matrix 3 as they pass through the material of the diamond matrix 3.

In order to introduce the ions in a targeted manner into the diamond matrix 3, the latter is masked beforehand. During this masking, only those regions on the surface of the diamond matrix 3 at which the vacancy centers 4 are subsequently intended to be located are left uncovered. The regions that are not masked during the ion implantation may for example be spaced apart from each other by approximately 5 nm to 100 μm, so that two vacancy centers 4 in the subsequent spin-information transport device 1 are arranged at a distance of approximately 5 nm to 100 μm from each other.

Following the ion implantation, a high-temperature annealing of the system consisting of diamond substrate 2 and diamond matrix 3 takes place. This high-temperature annealing takes place at a pressure of less than 10⁻⁷ mbar in vacuo, in order to be able to exclude unwanted chemical reactions. The system is heated to a temperature greater than 1000 °C for three hours. At these temperatures, the ions and vacancies implemented in the diamond matrix 3 can combine to form the vacancy centers 4. For example, by implanting nitrogen-15 ions and subsequently annealing at a high temperature, NV centers are introduced as vacancy centers 4 into the diamond matrix 3.

These vacancy centers 4 are indicated in the drawing as pairs of spots, which symbolize the combining of the implemented ions and vacancies. The arrows of these pairs symbolize the non-zero spins of the vacancy centers 4, with which they can couple to the subsequently formed spin polarization channel 6.

FIGS. 1c and 1d show the growth of a C13-enriched diamond layer 5 that takes place following the introduction of the vacancy centers 4. The diamond layer 5 is also grown on by means of CVD, and after being grown on has a thickness D of approximately 1 nm.

In a manner similar to when growing on the diamond matrix 3, a C12-containing gas, in particular methane gas, is used as the growth gas. However, this growth gas is enriched with C13. Therefore, the diamond layer 5 grown onto the diamond matrix 3 is also enriched with C13. This makes it possible to subsequently produce a spin polarization channel 6, which is arranged above the vacancy centers 4.

By enriching the diamond layer 5 with C13, said layer contains C13 atoms which have a non-zero nuclear spin. The C13 atoms are thus in contrast to the other, C12, atoms of the diamond layer 5, which are free of nuclear spin, i.e., have a nuclear spin of zero. With this nuclear spin, the C13 atoms can couple to the spins of the vacancy centers 4, thereby enabling transport of the spin polarization. The C13 atoms with nuclear spin are indicated in FIG. 1d as spots with arrows which symbolize the nuclear spins.

It can also be seen that the diamond matrix 3 arranged below the diamond layer 5 largely does not contain any diamond atoms with nuclear spin, since it comprises the nuclear spin-free C12 atoms. In the diamond layer 5, only the vacancy centers 4 have nuclear spin. A diffusion of the spin polarization from the vacancy centers 4 into the diamond matrix 3 is therefore not possible.

In the C13-enriched diamond layer 5, however, the spin polarization can diffuse in all directions. Therefore, no directional diffusion of spin polarization can be achieved with the diamond layer 5 shown in FIG. 1c and FIG. 1d.

To enable a directional diffusion of the spin polarization, a spin polarization channel 6 must be formed from the diamond layer 5, as shown in Fig. le. To do so, the C13-enriched diamond layer 5 is partially removed, so that only the spin polarization channel 6 remains.

A lithographic ICP etching process is used for this purpose. The region of the diamond layer 5 that is intended to form the spin polarization channel 6 is coated with a photoresist. The diamond layer 5 thus masked can be exposed to the plasma 9. In the unmasked regions, the C13-enriched diamond layer 5 is thus removed in a controlled manner.

After removal, all that remains of the C13-enriched diamond layer 5 is a long and thin spin polarization channel 6 consisting of C13-enriched diamond. In the exemplary embodiment shown, this spin polarization channel 6 has, after being formed, a width B in the range from 5 nm to 100 nm, a length L in the range from approximately 5 nm to 100 μm, and a thickness D in the range from 0.5 nm to 100 nm.

The spin polarization channel 6 still contains C13 atoms with nuclear spin. Since the spin polarization channel 6 is located above the vacancy centers 4 and extends between them, it enables a directional diffusion of spin polarization between the two vacancy centers 4.

Although the production of a single spin polarization channel 6 has been described above, multiple spin polarization channels 6 between different vacancy centers 4 of the diamond matrix 3 can also be produced in parallel in the same way. For instance, a spin-information transport device 1 can be produced with multiple spin polarization channels 6 on the same diamond matrix 3 in order to obtain, for example, quantum transistors or qubit registers.

FIG. 1f shows how, after the spin polarization channel 6 has been formed, the spin-information transport device 1 is additionally provided with a C12 diamond protective layer 7. For this purpose, the spin polarization channel 6 is covered with the C12 diamond protective layer 7.

The C12 diamond protective layer 7 is grown on by means of a CVD process in the same way as the diamond matrix 3. The spin polarization channel 6 and those regions of the diamond matrix 3 from which the diamond layer 5 has been completely removed serve as a base for the growth of the C12 diamond protective layer 7.

A C13-free growth gas 8 is used for the growth of the C12 diamond protective layer 7, so that the C12 diamond protective layer 7 is nuclear spin-free once growth is complete.

This C12 diamond protective layer 7 can protect the spin polarization channel 6 against negative external influences and can help to increase the coherence time of the vacancy centers 4. This is achieved in that the C12 diamond protective layer 7 is C13-free. It therefore has no diamond atoms with nuclear spin that could couple to the spins of the vacancy centers 4 or the spin polarization channel 6 and thus negatively affect the coherence time.

In addition, the C12 diamond protective layer 7 can serve as a protective layer for protecting the spin polarization channel 6 against mechanical damage.

With the C12 diamond protective layer 7, a spin-information transport device 1 can be provided which is even more stable and reliable than a spin-information transport device 1 without a diamond protective layer, as shown in FIG. 1e.

The C12 diamond protective layer 7 has a thickness S in the range from 50 nm to 100 nm. The C12 diamond protective layer may be equally as thick as the diamond matrix 3. In this way, the spin polarization channel 6 is symmetrically enclosed and protected in the middle of the layer system consisting of C12 diamond protective layer 7 and diamond matrix 3.

By means of the above-described spin-information transport device 1 and the method of manufacturing same, it is possible to provide a device by which spin information can be transported in a directional manner.

### LIST OF REFERENCE SIGNS

1 Spin-information transport device
2 Diamond substrate
3 Diamond matrix
4 Vacancy centers
5 Diamond layer
6 Spin polarization channel
7 C12 diamond protective layer
8 Growth gas
9 Plasma
B Width
D Thickness
L Length
M Thickness
S Thickness
W Direction of growth

1. A spin-information transport device, comprising a diamond matrix consisting of C12 diamond and two vacancy centers, in particular NV centers, within the diamond matrix, wherein a spin polarization channel, in particular consisting of C13-enriched diamond, for enabling a directional diffusion of a spin polarization, said spin polarization channel extending between the two vacancy centers.

2. The spin-information transport device according to claim 1, wherein the spin polarization channel is arranged above the vacancy centers.

3. The spin-information transport device according to claim 1, wherein the spin polarization channel is covered by a C12 diamond protective layer.

4. The spin-information transport device according to claim 1, wherein the diamond matrix is arranged on a diamond substrate.

5. The spin-information transport device according to claim 1, wherein the spin polarization channel has a width (B) of 1 nm to 10 μm, a length (L) of at least 5 nm, preferably at least 500 nm, particularly preferably in the range from 500 nm to 1 μm, and/or a thickness (D) in the range from 0.5 nm to 100 nm.

6. The spin-information transport device according to claim 1, wherein the diamond matrix has a thickness (M) of at least 50 nm, in particular at least 100 nm.

7. A method of manufacturing a spin-information transport device, comprising the steps of:
growing a diamond matrix consisting of C12-enriched diamond onto a diamond substrate, in particular an ultra-pure diamond substrate, by means of CVD;
introducing vacancy centers into the diamond matrix;
growing a C13-enriched diamond layer thereon; and,
partially removing the C13-enriched diamond layer, in particular by etching, to form a spin polarization channel.

8. The method according to claim 7, wherein a C12 diamond protective layer is grown onto the spin polarization channel in order to increase the coherence time of the vacancy centers.

9. The method according to claim 7, wherein the C13-enriched diamond layer is grown on by means of CVD using C13-enriched methane gas.

10. The method according to claim 7, wherein the partial removal of the C13-enriched diamond layer takes place by means of controlled plasma etching, in particular ICP, of the surface of the C13-enriched diamond layer.

11. The spin-information transport device according to claim 2, wherein the spin polarization channel is covered by a C12 diamond protective layer.

12. The spin-information transport device according to claim 2, wherein the diamond matrix is arranged on a diamond substrate.

13. The spin-information transport device according to claim 3, wherein the diamond matrix is arranged on a diamond substrate.

14. The spin-information transport device according to claim 2, wherein the spin polarization channel has a width (B) of 1 nm to 10 μm, a length (L) of at least 5 nm, preferably at least 500 nm, particularly preferably in the range from 500 nm to 1 μm, and/or a thickness (D) in the range from 0.5 nm to 100 nm.

15. The spin-information transport device according to claim 3, wherein the spin polarization channel has a width (B) of 1 nm to 10 μm, a length (L) of at least 5 nm, preferably at least 500 nm, particularly preferably in the range from 500 nm to 1 μm, and/or a thickness (D) in the range from 0.5 nm to 100 nm.

16. The spin-information transport device according to claim 4, wherein the spin polarization channel has a width (B) of 1 nm to 10 μm, a length (L) of at least 5 nm, preferably at least 500 nm, particularly preferably in the range from 500 nm to 1 μm, and/or a thickness (D) in the range from 0.5 nm to 100 nm.

17. The spin-information transport device according to claim 2, wherein the diamond matrix has a thickness (M) of at least 50 nm, in particular at least 100 nm.

18. The spin-information transport device according to claim 3, wherein the diamond matrix has a thickness (M) of at least 50 nm, in particular at least 100 nm.

19. The spin-information transport device according to claim 4, wherein the diamond matrix has a thickness (M) of at least 50 nm, in particular at least 100 nm.

20. The spin-information transport device according to claim 5, wherein the diamond matrix has a thickness (M) of at least 50 nm, in particular at least 100 nm.
